(19) United States
(12) Patent Application Publication
(10) Pub. No.: US 2011/0251809 A1
(43) Pub. Date: Oct. 13, 2011

(54) INDUCTIVE LOOP PRESENCE DETECTOR

(75) Inventor: Wayne E. Stollenwerk, Brookfield, WI (US)

(73) Assignee: AAA SALES & ENGINEERING, INC., Oak Creek, WI (US)

(21) Appl. No.: 12/902,649

(22) Filed: Oct. 12, 2010

Related U.S. Application Data
(60) Provisional application No. 61/250,644, filed on Oct. 12, 2009.

(51) Int. Cl. G06F 19/00; G01R 27/26

(52) U.S. Cl. 702/65; 324/656

(57) ABSTRACT

An inductive loop presence detector for sensing objects, such as rail cars, containing one or more sensing loops. The inductive loop presence detector includes a backup power supply that is connected to a control unit of the detector to power the control unit during an interruption in the line voltage. The backup power supply includes batteries or capacitors that power the control unit when the line voltage is interrupted. The control unit of the inductive loop presence detector operates in a lower power mode when the control unit is supplied with power from the backup power supply. The control unit operates to auto-tune and supply power to the sensing loops to operate at the most desirable frequency based upon the inductance of the sensing loops.

### CROSS-REFERENCE TO RELATED APPLICATION

The present application is based on and claims priority from U.S. Provisional Patent Application No. 61/250,644 filed Oct. 12, 2009.

### BACKGROUND OF THE INVENTION

The present disclosure generally relates to a system for detecting the presence of a rail car along a length of track. More specifically, the present disclosure relates to an inductive loop presence detector that includes both an automatic tuning circuit and a backup power supply that allows the presence detector to automatically calibrate upon initial startup and eliminates the need for recalibration due to brief power outages.

Since the inception of railroads, the control of trains along tracks, specifically along the multiple parallel, closely spaced tracks typically included in rail yards has been a priority and concern to prevent injury and damage. Part of the process of controlling the movement of trains through a rail yard requires the need for the automatic detection of rail cars along each two-rail track included in the rail yard. Since many switching and arresting devices are automatically controlled in a rail yard, identifying the presence of rail cars along the individual tracks is imperative to prevent collision and derailment.

One commonly used system for detecting the presence of rail cars within a rail yard utilizes a continuous inductive coil positioned along select lengths of each of the rail tracks. Each of the coils is formed from one or multiple windings of an electrically conductive material. When the rail car is present over the coil of wire, the inductance of the sensing coils is changed by eddy currents created in the metallic material of the rail car, which changes the electrical current generated within the inductive coil. The change in the inductance within the inductive coil is sensed by a control unit and results in a train presence signal. Although this type of train detector system has worked well for many years, the initial calibration of the system and recalibration of the system upon power loss are two shortcomings that can increase downtime within the rail yard.

### SUMMARY OF THE INVENTION

The present disclosure relates to an inductive loop presence detector and method for operating the presence detector. The presence detector detects the presence of an object, such as a rail car, and generates a detection signal to a remote monitoring location upon the detected presence of the rail car.

The inductive loop presence detector includes a control unit that receives operating power from a line voltage. Upon initial startup, the control unit powers the one or more sensing loops at a selected frequency. The power applied to the sensing loops creates a magnetic field above the sensing loops. The control unit receives a sensed signal from the sensing loops. The control unit operates to auto-tune the system by the self resonance of an LC oscillating circuit. If a metallic object, such as a rail car, moves within the magnetic field generated by the sensing loops, the control unit detects a change in the frequency of the sensed signal and generates a detection signal to a remote monitoring location. Preferably, the control unit compares the sensed signal to a stored reference frequency for the sensed signal and generates the detection signal when the sensed signal deviates from the stored reference value for the frequency of the sensed signal by more than a threshold value.

The inductive loop presence detector of the present disclosure includes a backup power supply that is connected to the control unit to supply a backup voltage to the control unit upon disruption to the line voltage. The backup power supply is able to power the control unit for a period of time until the line voltage returns.

In one embodiment of the disclosure, the backup power supply includes a pair of batteries that charge in parallel and discharge in series to power the control unit. In another contemplated embodiment, the batteries of the backup power supply can be replaced with super capacitors that charge and discharge in the same manner.

When the control unit determines that the line voltage has been interrupted and the system is operating on the backup power supply, the control unit enters into a low power mode. In the low power mode, the control unit turns off all local indicators to reduce the amount of current drawn from the backup power supply. The local indicators may include LEDs that are normally activated to indicate the present status of the inductive loop presence detector.

Various other features, objects and advantages of the invention will be made apparent from the following description taken together with the drawings.

### BRIEF DESCRIPTION OF THE DRAWINGS

The drawings illustrate the best mode presently contemplated of carrying out the disclosure. In the drawings:

FIG. 1 illustrates one embodiment of an inductive loop presence detector including one or more turns of a single sensing loop;

FIG. 2 illustrates a second embodiment of an inductive loop presence detector including a quad pole loop configuration;

FIG. 3 is a schematic illustration of the control unit and backup power supply in accordance with the present disclosure;

FIG. 4A illustrates the magnetic field generated by the sensing loops of the inductive loop presence detector;

FIG. 4B illustrates the presence of an object, such as a rail car, within the magnetic field generated by the sensing loops;

FIG. 4C illustrates the transition of a frequency signal generated when no object is present and upon the presence of an object over the inductive loop detector; and

FIG. 5 is a flowchart illustrating the operational sequence carried out by the control unit of the presence detector.

### DETAILED DESCRIPTION OF THE INVENTION

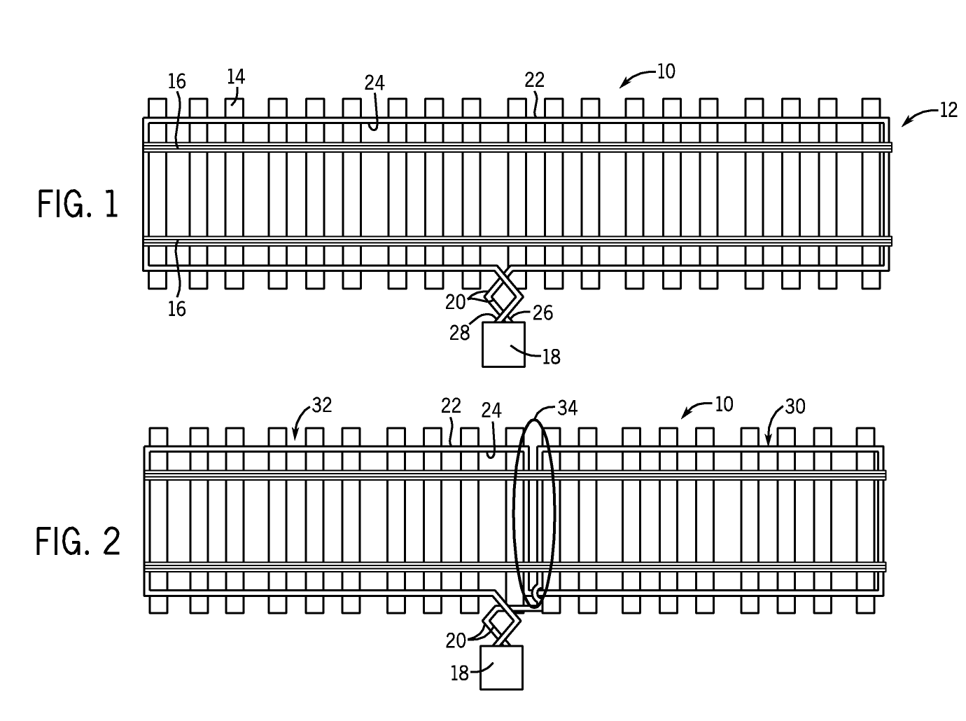

FIG. 1 illustrates a first embodiment of an inductive loop presence detector 10 constructed in accordance with the present disclosure. The inductive loop presence detector in the embodiment shown in FIG. 1 is utilized with a section of railroad track 12 including a series of ties 14 supporting a pair of metal rails 16. The railroad track 12 in the embodiment shown is one of a series of railroad tracks that may be located in a railroad yard. Although the present disclosure is shown and described as being utilized with a railroad track 12, the inductive loop presence detector 10 could be utilized in various other operating situations, such as when detecting the presence of a motor vehicle at a stop light or in other conventional implementations.

In the embodiment shown in FIG. 1, the inductive loop presence detector 10 includes a detector 18 that is connected to a pair of wires 20 that form a first sensing loop 22 and a second sensing loop 24. Together, the sensing loops 22, 24 are formed from a continuous loop of wire having a first end 26 connected to the detector 18 and a second end 28 also connected to the detector 18. The detector 18 includes a control unit (not shown) that powers both of the sensing loops with a low frequency signal that creates a magnetic field extending above both of the first and second sensing loops 22, 24.

In the embodiment illustrated in FIG. 1, each of the first and second sensing loops 22, 24 has a length from between twenty to one hundred feet long and a width of approximately five feet. However, it is contemplated that the length and width of each of the first and second sensing loops 22, 24 could be varied depending upon the particular implementation of the inductive loop presence detector 10.

FIG. 2 illustrates an alternate embodiment of the inductive loop presence detector 10. In the embodiment shown in FIG. 2, the pair of wires 20 connected to the detector 18 form a quad pole loop. The quad pole loop shown in FIG. 2 includes a first lobe 30 and a second lobe 32 that cross over with each other in an enhanced detection zone 34. The quad pole loop shown in FIG. 2 is a common design and has the benefit of an increased sensitivity in the cross over zone, which is labeled as detection zone 34 in FIG. 2.

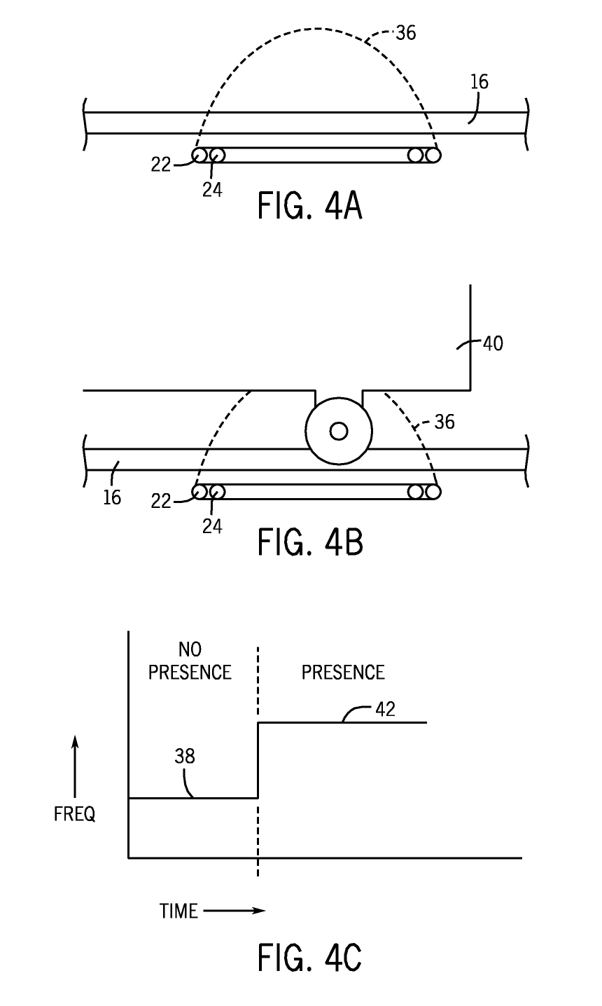

FIG. 4A generally illustrates the operation of the loop presence detector of the present disclosure. As illustrated in FIG. 4A, the first and second sensing loops are positioned outside the metal rail 16 and generate a magnetic field 36 that extend approximately 3-5 feet above the first and second sensing loops 22, 24. When no object is present above the loops 22 and 24, the first and second sensing loops 22, 24 resonate at a constant reference frequency 38 (FIG. 4C) that is detected within the control unit of the detector 18 of FIG. 1. As illustrated in FIG. 4C, the resonant frequency 38 remains generally constant over time as long as no object is positioned within the magnetic field 36.

When a conductive object, such as the rail car 40, enters the area above the first and second sensing loops 22, 24 as shown in FIG. 4B, the magnetic field generated by the alternating electric current in the signal detector circuit induces weak electrical currents in the conductive object. The electrical currents induced in the object generate their own magnetic field that works in opposition to the magnetic field generated by the sensor coil. The opposition changes the resonant frequency of the sensor circuit by reducing the effective inductance of the sensor coil. As illustrated in FIG. 4C, the frequency is increased as illustrated by reference numeral 42 when a metallic object is present. The increased frequency is detected by the control unit in the detector as a sensed signal from the pair of sensing loops 22, 24. Preferably, when the frequency of the sensed signal rises above the reference frequency by more than a predetermined threshold value, the detector will generate a detection signal that indicates that an object is present within the pair of sensing loops 22, 24.

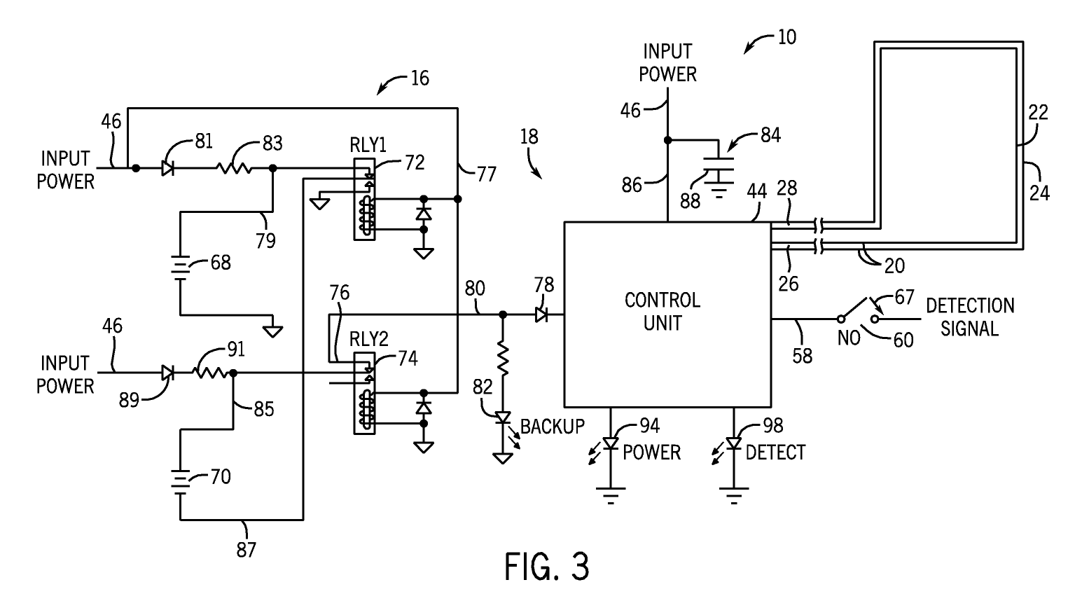

FIG. 3 illustrates the operating components of the detector 18 of the inductive loop presence detector 10. The system includes a control unit 44 that receives power from a line voltage 46. Although not shown in FIG. 3, the line voltage 46 is reduced and converted as required to provide the required voltage to power the control unit 44. The control unit 44 is connected to the first end 26 and the second end 28 of the pair of wires 20 that form the first sensing loop 22 and the second sensing loop 24.

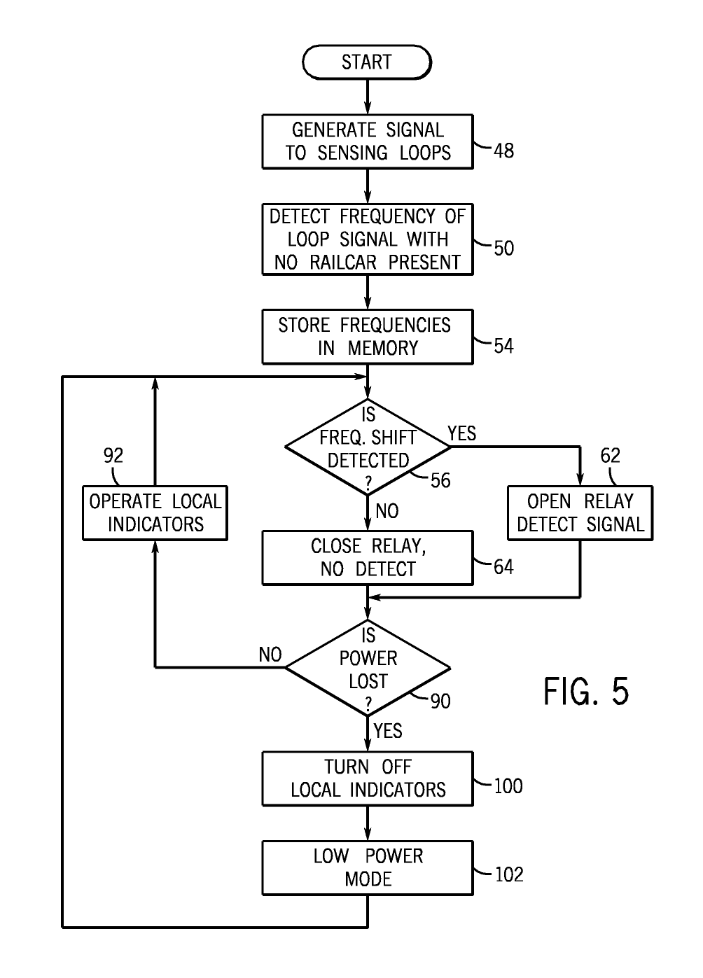

Referring now to FIG. 3, during the initial startup of the inductive loop presence detector 10, the control unit 44 is initially powered on and generates an AC signal across the pair of wires 20, as indicted by step 48 in FIG. 5. As indicated previously, the signal supplied to the sensing loops 22, 24 creates a magnetic field that causes the loops to resonate at a constant frequency that is detected by the control unit in step 50. Since the inductive loop presence detector 10 may be located in a physical area that includes other detectors or other sources of interference, the control unit can be manually adjusted to different frequencies if interference is present. The frequency will self-adjust to slow changes as seen under normal environmental changes. The control unit continues this process until the control unit distinguishes between changes from environmental conditions and changes due to the presence of an object, such as a rail car. The frequency of the supplied signal and the corresponding frequency of the sensed signal are stored within memory of the control unit, as illustrated by step 54 in FIG. 5. The frequency of the sensed signal from the sensing loops is stored as a reference frequency in the control unit. In this manner, the control unit 44 is able to tune itself to the most desirable frequency.

In the embodiment illustrated, the control unit is operable to adjust the frequency of the signal applied to the sensing loops over a range of approximately 13 kHz to 130 kHz. This relatively large frequency range allows the control unit to be configured to avoid other disturbances or magnetic fields in the area close to the inductive loop presence detector.

The control unit continues to power the sensing loops at the selected frequency and monitors for the frequency returned from the sensing loops as long as power is supplied to the control unit. In step 56, the control unit determines whether the sensed signal from the sensing loops has been shifted relative to the reference frequency determined when no object is present. As previously discussed with reference to FIGS. 4A-4C, when an object is present within the magnetic field 36 generated by the first and second sensing loops 20, 24, the frequency returned to the detector is increased from the reference frequency 38 to the increased frequency 42. If the difference between the reference frequency 38 and the detected frequency 42 is greater than a threshold value, the control unit generates a detection signal. In the embodiment of FIG. 3, the detection signal is generated by the control unit 44 allowing the normally open relay 60 to remain in its open position, as illustrated by step 62 in FIG. 5. Referring back to FIG. 3, the relay 60 is a normally open relay such that should power be interrupted to the control unit 44 or should the control unit 44 malfunction, the relay 60 defaults to its normally open position, which is interpreted by the remote monitoring location as a “detect” condition.

Referring back to FIG. 5, if the control unit determines in step 56 that a frequency shift was not detected, the control unit generates a signal along the output line 58 of FIG. 3 to cause the relay 60 to move to a closed condition, as indicated by step 64. When the relay 60 moves in the direction illustrated by arrow 67, the relay closes, which is interpreted by the remote monitoring station that no object is being sensed. Thus, the control unit 44 must take a positive step to close the relay 60 for a “no object present” signal to be interpreted by the monitoring station at a remote location.

As can be understood by the above description, the control unit 44 can close the relay 60 to generate a “no object present” indication only when power is being supplied to the control unit. In accordance with the present disclosure, a backup power supply 66 provides temporary power to the control unit 44 such that the control unit 44 can continue to operate the inductive loop presence detector 10 for relatively short periods of time until the line voltage 46 returns. Although a specific embodiment of the backup power supply 66 is shown in FIG. 3, it should be understood that different types of backup power supplies could be utilized while operating within the scope of the present disclosure. The backup power supply 66 shown in FIG. 3 will now be described in detail.

The backup power supply 66 includes a first battery 68 and a second battery 70. The first and second batteries 68, 70 are connected to each other and to the control unit 44 through a pair of three wire relays 72, 74. The output pin 76 of the second relay 74 is connected to the control unit 44 through diode 78 to supply power from the backup power supply 66 to the control unit 44 upon an interruption in the line voltage 46.

When the line voltage is present, each of the relays 72, 74 is powered through line 77. When the relays are powered, the first end 79 of the battery 68 is connected to an open circuit in the relay 72 such that battery 68 is charged by the line voltage 46 through the diode 81 and resistor 83. Likewise, when relay 74 is receiving power from the line voltage, the first end 85 of battery 70 is connected to an open circuit in relay 74 and the second end 87 of battery 70 is connected to ground through relay 72. When battery 70 is connected to ground, battery 70 is charged in parallel with battery 68 through diode 89 and resistor 91. In this condition, no power is supplied to the control unit 44 from the pair of batteries 68, 70.

Upon power interruption, each of the relays 72, 74 move to their normal position, as shown in FIG. 3. In this position, the first end 79 of battery 68 is connected to the second end 87 of battery 70 through the relay 72. The first end 85 of battery 70, in turn, is connected to pin 76 through relay 74. Thus, the batteries 68, 70 are connected in series and supply power through the diode 78 to the control unit 44. In the embodiment illustrated, each of the batteries 68, 70 are 15-volt lead acid batteries that are able to supply electric power to the control unit 44 to power the control unit for between five to six hours.

Although the embodiment of backup power supply 66 shown in FIG. 3 includes a pair of batteries 68, 70, it is contemplated that the batteries could be replaced with super capacitors that charge and discharge in a similar manner as the batteries 68, 70. However, when utilizing super capacitors, it is contemplated that the backup power supply 66 would only be able to power the control unit for a much shorter period of time, such as five to ten minutes. Although an embodiment that includes super capacitors has a much shorter duration, super capacitors have a much longer life as compared to lead acid batteries and thus require less maintenance and replacement. In either case, the backup power supply 66 will be able to supply power to control unit 44 for a period of time during power interruption.

When power is being supplied to the control unit 44 from the backup power supply 66, the voltage present at line 80 activates a backup LED 82 which causes the backup LED 82 to generate a visual indication that the control unit 44 is being operated from the backup power supply 66.

As previously described, the control unit 44 receives input power from the line voltage 46 during normal operating conditions. In the embodiment shown in FIG. 3, an interrupt power supply 84 is also included in the circuit to provide the instantaneous power required to keep the relay 60 in an open condition if power is interrupted to the control unit 44. In the embodiment illustrated, the interrupt power supply 84 is a capacitor 88 connected to the input line 86 that feeds the control unit 44. The value of the capacitor 88 is selected such that the capacitor 88 can supply the required amount of current to keep the relay 60 in its open position until the control unit 44 begins receiving power from the backup power supply 66. In the embodiment illustrated in FIG. 3, the capacitor 88 is a 100 μF capacitor. However, the value of the capacitor 88 could change depending upon the specific relay 60 and the current draw and timing needed.

Referring back to FIG. 5, if the line voltage is present, which the control unit senses in step 90, the control unit activates a series of local indicators, as indicated in step 92. As illustrated in FIG. 3, the local indicators include a power LED 94 and a detect LED 98. Typically, the local indicators 94 and 98 are located as part of the housing that includes the control unit 44. The local indicators 94 and 98 allow service personnel located at the control unit to determine whether the control unit 44 is operating correctly. When the control unit is receiving power from the line voltage, the current draw of the local indicators 94 and 98 is inconsequential. However, when the control unit 44 is being powered by the backup power supply 66, the current draw from each of these indicators will reduce the amount of time the control unit 44 can operate on the backup power supply. As an example, if the backup power supply 66 includes super capacitors rather than the batteries 68, 70, the five to six minute operating time for the control unit may be significantly reduced by powering the local indicators 94 and 98.

As indicated in FIG. 5, when the control unit determines in step 90 that power has been lost, the control unit turns off the local indicators in step 100 and begins to operate in a low power mode in step 102. The lower power mode prevents the operation of the local indicators and conserves the current draw by the control unit in any manner possible. Although the control unit operates in the low power mode, when operating in such mode, the control unit can still control the opening and closing of the relay 60 shown in FIG. 3 to provide an indicator to the remote monitoring station.

As described previously, following the initial setup of the inductive loop proximity sensor, the frequency of the signal returned from the sensing loops and the reference frequency are each stored within a memory location within the control unit. Since the control unit 44 is connected to the backup power supply 66 and continues to receive power upon an interruption in the line voltage, the frequency values determined during the initial startup remain stored in memory within the control unit. If the control unit 44 needs to restart due to the power loss, the control unit 44 recalibrates. If a car is present during startup, it will reset once the rail car leaves the detection zone. Thus, the control unit 44 can restart with an object located within the sensing loops. In prior art systems that do not include memory locations for storing the reference frequency, rail cars must be moved away from the sensing loops and the system recalibrated with no object present. The ability of the control unit 44 to store the reference frequency allows the system to restart without having to move rail cars away from the sensing loops.

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. An inductive loop presence detector powered by a line voltage, comprising:
a control unit that receives operating power from the line voltage;
one or more sensing loops connected to the control unit, wherein the control unit powers the sensing loops and detects the presence or lack of presence of an object within the sensing loops based upon a sensed signal from the sensing loops; and
a backup power supply connected to the control unit to supply a backup voltage to the control unit upon interruption of the line voltage.

2. The inductive loop presence detector of claim 1 further comprising an indicator relay selectively operable by the control unit to indicate the presence or lack of presence of the object.

3. The inductive loop presence detector of claim 2 wherein the relay is normally open such that upon loss of power, the relay opens to generate a presence signal.

4. The inductive loop presence detector of claim 3 further comprising an interrupt power supply connected to the control unit to power the relay immediately upon power loss and before connection to the backup power supply.

5. The inductive loop presence detector of claim 1 wherein the backup power supply includes at least one battery.

6. The inductive loop presence detector of claim 1 wherein the backup power supply includes at least one storage capacitor.

7. The inductive loop presence detector of claim 1 wherein the backup power supply is connected to the line voltage to charge the backup power supply.

8. The inductive loop presence detector of claim 4 wherein the interrupt power supply is a storage capacitor.

9. The inductive loop presence detector of claim 1 further comprising one or more indicators connected to the control unit and positioned in close proximity thereto, wherein the control unit does not operate the local indicators upon connection to the backup power supply.

10. A method of operating an inductive loop presence detector having one or more sensing loops, the method comprising the steps of:
generating a signal from the control unit to the sensing units;
detecting a frequency of a sensed signal from the sensing loops when no object is positioned within the sensing loops;
storing the sensed frequency as a reference frequency in a memory of the control unit;
continuously monitoring the frequency of the sensed signal;
comparing the frequency of the sensed signal to the reference frequency; and
generating a signal to indicate the presence of an object when the difference between the frequency of the sensed signal and the reference frequency exceeds a threshold value.

11. The method of claim 10 further comprising the steps of:
retrieving the reference frequency from memory following a loss of power to the control unit; and
monitoring the difference between the frequency of the sensed signal and the reference frequency upon application of power to the control unit.

12. The method of claim 10 further comprising the step of modifying the detecting frequency of the signal from the control unit such that the reference frequency of the sensed signal when no object is present is above a strength threshold.

13. A method of operating an inductive loop presence detector having one or more sensing loops and powered by a line voltage, the method comprising the steps of:
generating a signal from the control unit to the sensing loops;
detecting a reference frequency of a sensed signal from the sensing loops when no object is present;
generating an indicator signal when the frequency of the sensed signal changes relative to the reference frequency to indicate the presence of an object within the sensing loops;
monitoring for a loss of the line voltage; and
operating the control unit in a low power mode upon loss of the line voltage.

14. The method of claim 13 further comprising the steps of
supplying power to the control unit from a backup power supply upon loss of the line voltage; and
discontinuing operation of local indicators when the control unit is being operated with a backup power supply.

15. The method of claim 13 further comprising the step of modifying the frequency of the signal from the control unit to the sensing loops such that the reference frequency of the sensed signal is optimized.

16. The method of claim 13 wherein the detected reference frequency is stored in memory of the control unit.

17. The method of claim 16 further comprising the steps of:
retrieving the reference frequency from memory following a loss of power to the control unit; and
monitoring the difference between the frequency of the sensed signal and the reference frequency upon application of power to the control unit such that the control unit can determine the presence of an object upon application of power to the control unit.

18. The method of claim 13 wherein the indicator signal is applied to a relay such that the position of the relay indicates the presence of an object.

19. The method of claim 18 wherein the relay is biased such that upon loss of power, the relay indicates a presence of an object.
